(19) United States
(12) Patent Application Publication
(10) Pub. No.: US 2009/0091397 A1
(43) Pub. Date: Apr. 9, 2009

(54) OSCILLATING APPARATUS AND FREQUENCY CONVERT APPARATUS

(75) Inventors: HARUKI NAGAMI, TOKYO (JP); HIDEO HARA, TOKYO (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANTEST CORPORATION, TOKYO (JP)

(21) Appl. No.: 11/868,536

(22) Filed: Oct. 8, 2007

(51) Int. Cl. H03B 1/00; H03B 21/02

(52) U.S. Cl. 331/40; 331/74

(57) ABSTRACT

An oscillating apparatus for outputting an oscillating signal includes a resonant circuit that generates the oscillating signal, an amplifier circuit that amplifies the oscillating signal generated by the resonant circuit, and feeds the amplified oscillating signal back to the resonant circuit, and an output circuit that receives the oscillating signal which is supplied to the amplifier circuit, and outputs the received oscillating signal to outside. Here, the output circuit includes a first buffer that (i) receives at an input end thereof the oscillating signal which is supplied to the amplifier circuit and outputs the received oscillating signal, and (ii) uses a capacitance component of the input end to feed a first current signal back to the amplifier circuit, wherein the first current signal has a phase displaced from a phase of a voltage component of the oscillating signal, and a second buffer that (I) receives at an input end thereof the oscillating signal which is output from the first buffer and outputs the received oscillating signal, and (II) uses a capacitance component of the input end to feed a second current signal back to the first buffer, wherein the second current signal has a phase displaced from a phase of a voltage component of the oscillating signal which is output from the first buffer.

### BACKGROUND

1. Technical Field

The present invention relates to an oscillating apparatus and a frequency converting apparatus. More particularly, the present invention relates to an oscillating apparatus and a frequency converting apparatus that are capable of varying the frequency of an oscillating signal.

2. Related Art

A test apparatus for testing communication devices includes therein an oscillating apparatus to generate a local signal for modulation and demodulation. A recent demand for testing high-frequency communication devices requires the test apparatus to have an oscillating apparatus with a broader frequency band which is capable of outputting an oscillating signal having a frequency of several GHz to several dozen GHz.

It should be noted here that a circuit outputting a high-frequency signal is affected by reflection from a circuit of the following stage. For example, an oscillating apparatus which is capable of outputting an oscillating signal having a frequency of several GHz to several dozen GHz is affected by reflection from a buffer circuit which is a circuit of the following stage. If this is the case, the output power of the oscillating apparatus may drop.

### SUMMARY

Therefore, it is an object of an aspect of the present invention to provide an oscillating apparatus and a frequency converting apparatus, which are capable of overcoming the above drawbacks accompanying the related art. The above and other objects can be achieved by combinations described in the independent claims. The dependent claims define further advantageous and exemplary combinations of the present invention.

According to a first aspect related to the innovations herein, one exemplary oscillating apparatus may include an oscillating apparatus for outputting an oscillating signal. The oscillating apparatus includes a resonant circuit that generates the oscillating signal, an amplifier circuit that amplifies the oscillating signal generated by the resonant circuit, and feeds the amplified oscillating signal back to the resonant circuit, and an output circuit that receives the oscillating signal which is supplied to the amplifier circuit, and outputs the received oscillating signal to outside. Here, the output circuit includes a first buffer that (i) receives at an input end thereof the oscillating signal which is supplied to the amplifier circuit and outputs the received oscillating signal, and (ii) uses a capacitance component of the input end to feed a first current signal back to the amplifier circuit, wherein the first current signal has a phase displaced from a phase of a voltage component of the oscillating signal, and a second buffer that (I) receives at an input end thereof the oscillating signal which is output from the first buffer and outputs the received oscillating signal, and (II) uses a capacitance component of the input end to feed a second current signal back to the first buffer, wherein the second current signal has a phase displaced from a phase of a voltage component of the oscillating signal which is output from the first buffer.

According to a second aspect related to the innovations herein, one exemplary frequency converting apparatus may include a frequency converting apparatus that converts a frequency of an input signal in accordance with a frequency of a local signal. The frequency converting apparatus includes an oscillating apparatus that generates an oscillating signal and outputs the generated oscillating signal as the local signal, a mixer that multiplies together the local signal and the input signal, and a filter that passes therethrough a predetermined frequency component of a signal output from the mixer. Here, the oscillating apparatus includes a resonant circuit that generates the oscillating signal, an amplifier circuit that amplifies the oscillating signal which is generated by the resonant circuit and feeds the amplified oscillating signal back to the resonant circuit, and an output circuit that receives the oscillating signal which is supplied to the amplifier circuit and outputs the received oscillating signal to outside. The output circuit includes a first buffer that (i) receives at an input end thereof the oscillating signal which is supplied to the amplifier circuit and outputs the received oscillating signal, and (ii) uses a capacitance component of the input end to feed a first current signal back to the amplifier circuit, wherein the first current signal has a phase displaced from a phase of a voltage component of the oscillating signal, and a second buffer that (I) receives at an input end thereof the oscillating signal which is output from the first buffer and outputs the received oscillating signal, and (II) uses a capacitance component of the input end to feed a second current signal back to the first buffer, wherein the second current signal has a phase displaced from a phase of a voltage component of the oscillating signal which is output from the first buffer.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 illustrates the configuration of an oscillating apparatus 10 relating to an embodiment of the present invention.

FIG. 2 illustrates the configuration of an oscillator 20 relating to the embodiment of the present invention.

FIG. 3 illustrates the closed loop transfer characteristic of the gain of an output circuit 56, which receives an oscillating signal 530 output from a resonant circuit 52 and outputs a reflection signal to an amplifier circuit 54.

FIG. 4 illustrates an exemplary circuit configuration of the oscillator 20 that outputs the oscillating signal 530 which is a differential signal.

FIG. 5 illustrates an exemplary circuit configuration of the output circuit 56 which receives the oscillating signal 530 which is a differential signal from the amplifier circuit 54, together with the amplifier circuit 54.

FIG. 6 illustrates an exemplary circuit configuration of a constant current circuit 80.

FIG. 7 illustrates the configuration of a frequency converting apparatus 300 relating to an embodiment of the present invention.

### DESCRIPTION OF EXEMPLARY EMBODIMENTS

Hereinafter, an aspect of the present invention will be described through some embodiments. The embodiments do not limit the invention according to the claims, and all the combinations of the features described in the embodiments are not necessarily essential to means provided by aspects of the invention.

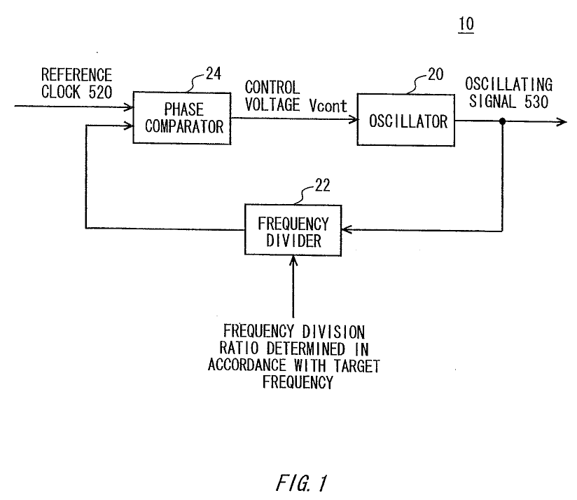

FIG. 1 illustrates the configuration of an oscillating apparatus 10 relating to an embodiment of the present invention. The oscillating apparatus 10 outputs an oscillating signal 530 which has a frequency determined in accordance with a target frequency which is supplied thereto from outside. For example, the oscillating apparatus 10 is capable of varying the frequency of the oscillating signal 530 in such a manner that the frequency of the oscillating signal 530 falls within a range of, for example, +−0.5 GHz of a given frequency ranging from no less than 6 GHz to no more than several dozen GHz.

The oscillating apparatus 10 includes therein an oscillator 20, a frequency divider 22 and a phase comparator 24. The oscillator 20 outputs the oscillating signal 530 having the frequency determined in accordance with a control signal supplied to the oscillating apparatus 10. According to the present embodiment, the oscillator 20 may be a voltage controlled oscillator (VCO) that outputs the oscillating signal 530 having the frequency determined in accordance with a control voltage Vcont supplied thereto, for example.

The frequency divider 22 outputs a frequency-divided signal which is obtained by dividing the frequency of the oscillating signal 530. The frequency divider 22 receives, from outside, a frequency division ratio which is determined in accordance with the target frequency. For example, the frequency division ratio may be equal to a value obtained by dividing the target frequency by the frequency of a reference clock 520. Having such a configuration, the frequency divider 22 can output the frequency-divided signal whose frequency is equal to the frequency of the reference clock 520 and whose phase is synchronized with the phase of the oscillating signal 530.

The phase comparator 24 compares the oscillating signal 530 and the reference clock 520 in terms of phase. The phase comparator 24 controls the frequency of the oscillating signal 530 output from the oscillator 20 based on the result of the comparison. For example, the phase comparator 24 detects a difference in phase between the frequency-divided signal output from the frequency divider 22 and the reference clock 520. The phase comparator 24 subsequently determines the value of the control voltage Vcont in accordance with the detected difference in phase, and supplies the determined control voltage Vcont to the oscillator 20, to cause the oscillator 20 to output the oscillating signal 530 having such a frequency that the difference in phase between the frequency-divided signal and the reference clock 520 becomes zero.

The above-described oscillating apparatus 10 is capable of outputting the oscillating signal 530 whose phase is synchronized with the phase of the reference clock 520 and whose frequency is equal to the target frequency supplied thereto. Here, the oscillating apparatus 10 may be configured without the frequency divider 22. If such is the case, the phase comparator 24 compares the oscillating signal 530 output from the oscillator 20 and the reference clock 520 in terms of phase.

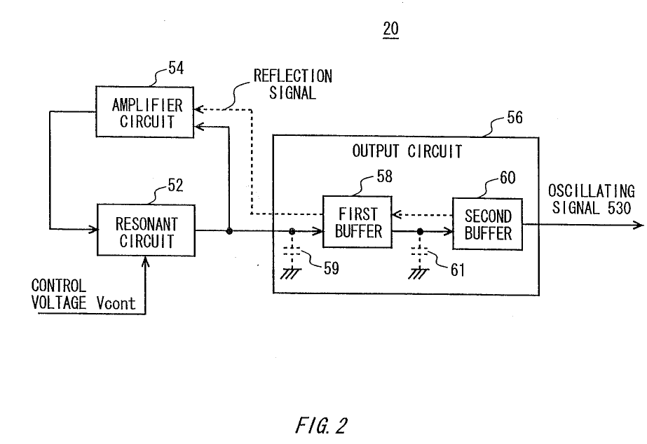

FIG. 2 illustrates the configuration of the oscillator 20 relating to the present embodiment. The oscillator 20 includes therein a resonant circuit 52, an amplifier circuit 54, and an output circuit 56.

The resonant circuit 52 generates the oscillating signal 530 having the frequency determined in accordance with the control voltage Vcont supplied thereto from the phase comparator 24. For example, the resonant circuit 52 may be an LC circuit whose resonant frequency varies in accordance with the control voltage Vcont. With such a configuration, the resonant circuit 52 passes therethrough the resonant frequency component of the signal supplied thereto from the amplifier circuit 54, and attenuates other frequency components of the signal received from the amplifier circuit 54. In this way, the resonant circuit 52 can generate the oscillating signal 530 having the frequency determined in accordance with the control voltage Vcont supplied thereto from the phase comparator 24.

The amplifier circuit 54 amplifies the oscillating signal 530 generated by the resonant circuit 52, and feeds the amplified oscillating signal 530 back to the resonant circuit 52. In more detail, the amplifier circuit 54 amplifies the oscillating signal 530 generated by the resonant circuit 52 based on positive feedback, and supplies the amplified oscillating signal 530 to the resonant circuit 52. Which is to say, the amplifier circuit 54 functions as a negative resistance which is connected to the input and output of the resonant circuit 52 so as to be positioned therebetween.

The above-described resonant circuit 52 and amplifier circuit 54 can continuously output the oscillating signal 530 having the frequency determined in accordance with the control voltage Vcont. In other words, the resonant circuit 52 and amplifier circuit 54 can perform an oscillation operation.

The output circuit 56 receives the oscillating signal 530 which is supplied from the resonant circuit 52 to the amplifier circuit 54, and outputs the received oscillating signal 530 to outside. For example, the output circuit 56 may be a circuit that has high input impedance and low output impedance. The output circuit 56 having such a configuration prevents the change or the like of the load of an external circuit of the following stage from affecting the resonant circuit 52 and amplifier circuit 54, and can stably output the oscillating signal 530.

The output circuit 56 includes therein a first buffer 58 and a second buffer 60. The first buffer 58 receives at the input end thereof the oscillating signal 530 which is supplied from the resonant circuit 52 to the amplifier circuit 54, and outputs the received oscillating signal 530 to the second buffer 60 of the following stage. The first buffer 58 has a capacitance component 59 at the input end thereof. For example, the first buffer 58 may be an emitter follower circuit formed by using a transistor. In this case, the capacitance component 59 at the input end of the first buffer 58 may be a base capacitance of the transistor which functions as the emitter follower circuit, for example.

The second buffer 60 receives at the input end thereof the oscillating signal 530 output from the first buffer 58, and outputs the received oscillating signal 530 to an external circuit of the following stage. The second buffer 60 has a capacitance component 61 at the input end thereof. For example, the second buffer 60 may be an emitter follower circuit formed by using a transistor. In this case, the capacitance component 61 at the input end of the second buffer 60 may be a base capacitance of the transistor which functions as the emitter follower circuit, for example.

Here, the output circuit 56 receives the oscillating signal 530 with a high frequency from the resonant circuit 52 of the preceding stage. For example, the output circuit 56 receives the oscillating signal 530 having a frequency within a range from no less than 6 GHz to no more than several dozen GHz, from the resonant circuit 52 of the preceding stage. The first buffer 58 receives, at the input end thereof, the oscillating signal 530 which is supplied to the amplifier circuit 54 and outputs the received oscillating signal 530. At the same time, the first buffer 58 uses the capacitance component 59 at the input end thereof to feed a first current signal back to the amplifier circuit 54. Here, the first current signal has a phase displaced from the phase of the voltage component of the oscillating signal 530. In other words, the first buffer 58 outputs, to the amplifier circuit 54, a reflection signal whose phase is delayed compared with the phase of the oscillating signal 530 which is supplied to the amplifier circuit 54.

Similarly, the second buffer 60 receives, at the input end thereof, the oscillating signal 530 which is output from the first buffer 58 and outputs the received oscillating signal 530. At the same time, the second buffer 60 uses the capacitance component 61 at the input end thereof to feed a second current signal back to the first buffer 58. Here, the second current signal has a phase displaced from the phase of the voltage component of the oscillating signal 530 which is output from the first buffer 58. In other words, the second buffer 60 outputs, to the first buffer 58, a reflection signal whose phase is delayed compared with the phase of the oscillating signal 530 which is output from the first buffer 58.

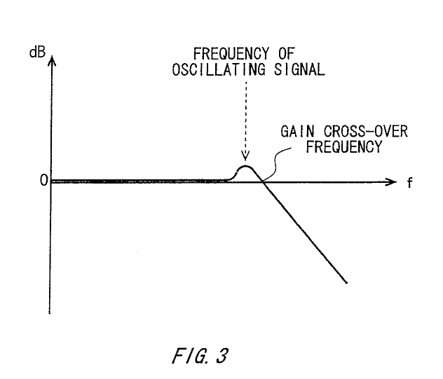

FIG. 3 illustrates the closed loop transfer characteristic of the gain of the output circuit 56 (hereinafter referred to as the reflection transfer characteristic of the output circuit 56) which receives the oscillating signal 530 output from the resonant circuit 52 and outputs the reflection signal to the amplifier circuit 54. Having the capacitance components 59 and 61 at the input ends thereof, the first and second buffers 58 and 60 respectively output, from the input ends thereof to the circuits of the preceding stage, the reflection signals whose phases are delayed by an angle ranging from 0° to less than 90° with respect to the phases of the signals supplied thereto from the circuits of the preceding stage. In other words, the first and second buffers 58 and 60 respectively have reflection transfer characteristics of first-order lag.

The output circuit 56 as a whole has a reflection transfer characteristic of second-order lag, since the two stages of the first-order lag systems are connected in series therein. Therefore, the output circuit 56 as a whole has such a reflection transfer characteristic that the gain is substantially 0 dB in the low-frequency region and is higher than 0 dB in the vicinity of the resonant frequency, as illustrated in FIG. 3. In addition, the output circuit 56 has such a reflection transfer characteristic that the gain attenuates at the rate of −40 dB/dec in the frequency region covering frequencies higher than the gain cross-over frequency. In the vicinity of the resonant frequency, the phase of the reflection signal is displaced by an angle of substantially −90° with respect to the phase of the input signal.

As described above, when the resonant frequency of the output circuit 56 is substantially equal to the target frequency of the oscillating signal 530, the reflection signal has a gain higher than 0 dB. Therefore, the output circuit 56 can feed power back to the amplifier circuit 54. For this reason, the output circuit 56 may be designed so as to have such a reflection transfer characteristic that the resonant frequency of the output circuit 56 is substantially equal to the target frequency of the oscillating signal 530. In this way, the output circuit 56 can feed power back to the amplifier circuit 54, so as to reduce the attenuation of the gain of the oscillating signal 530 which is output from the resonant circuit 52. As a result, the oscillator 20 can reduce the power loss, and perform an efficient oscillation operation.

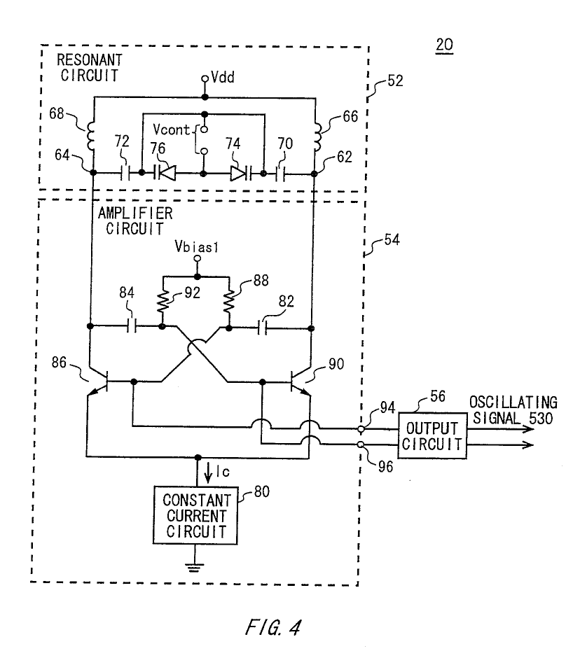

FIG. 4 illustrates an exemplary circuit configuration of the oscillator 20 outputting the oscillating signal 530 which is a differential signal. For example, the oscillator 20 may output the oscillating signal 530 which is a differential signal and has a frequency determined in accordance with the control voltage Vcont supplied thereto.

For example, the resonant circuit 52 may include therein a positive-side resonance inductor 66, a negative-side resonance inductor 68, a positive-side resonance capacitor 70, a negative-side resonance capacitor 72, a positive-side variable capacitance diode 74, and a negative-side variable capacitance diode 76. The resonant circuit 52 outputs, from a first contact point 62, the oscillating signal 530 which has not been inverted. Also, the resonant circuit 52 outputs, from a second contact point 64, the oscillating signal 530 which has been inverted.

The positive-side resonance inductor 66 is connected to the power source voltage (Vdd) and the first contact point 62 so as to be positioned therebetween. The negative-side resonance inductor 68 is connected to the power source voltage (Vdd) and the second contact point 64 so as to be positioned therebetween.

The positive-side resonance capacitor 70 is connected to the first contact point 62 at one end thereof, and connected to the cathode of the positive-side variable capacitance diode 74 at the other end thereof. The negative-side resonance capacitor 72 is connected to the second contact point 64 at one end thereof, and connected to the cathode of the negative-side variable capacitance diode 76 at the other end thereof. Here, the anode of the positive-side variable capacitance diode 74 is connected to the anode of the negative-side variable capacitance diode 76.

The positive-side variable capacitance diode 74 and negative-side variable capacitance diode 76 each receive the control voltage Vcont which is supplied from the phase comparator 24. The capacitance of each of the positive-side variable capacitance diode 74 and negative-side variable capacitance diode 76 varies in accordance with the control voltage Vcont.

In the resonant circuit 52 configured in the above-described manner, the resonant frequency of the impedance between the first contact point 62 and the second contact point 64 varies in accordance with the control voltage Vcont supplied to the resonant circuit 52. Therefore, the resonant circuit 52 can output the oscillating signal 530 which is a differential signal and has a frequency determined in accordance with the control voltage Vcont supplied thereto.

For example, the amplifier circuit 54 may include therein a constant current circuit 80, a positive-side capacitor 82, a negative-side capacitor 84, a first amplification transistor 86, a negative-side bias resistance 88, a second amplification transistor 90, and a positive-side bias resistance 92. The amplifier circuit 54 receives, from the first contact point 62, the oscillating signal 530 which has not been inverted, inverts and amplifies the oscillating signal 530, and feeds the inverted and amplified oscillating signal 530 back to the second contact point 64. The amplifier circuit 54 also receives, from the second contact point 64, the oscillating signal 530 which has been inverted, inverts and amplifies the received oscillating signal 530, and feeds the inverted and amplified the oscillating signal 530 back to the first contact point 62.

The amplifier circuit 54 outputs, from a positive-side oscillating signal output end 94, the oscillating signal 530 which has not been inverted. The amplifier circuit 54 also outputs, from the negative-side oscillating signal output end 96, the oscillating signal 530 which has been inverted.

The constant current circuit 80 passes a predetermined current Ic therethrough to the ground. To be more specific, the constant current circuit 80 sets, as the fixed value Ic, the total value obtained by combining the current that flows from the first contact point 62 to the ground via the amplifier circuit 54 and the current that flows from the second contact point 64 to the ground via the amplifier circuit 54.

The positive-side capacitor 82 is connected in series with the first contact point 62 on the resonant circuit 52 and the positive-side oscillating signal output end 94 so as to be positioned between the first contact point 62 and positive-side oscillating signal output end 94. The positive-side capacitor 82 can block the current that flows from the first contact point 62 to the positive-side oscillating signal output end 94.

The negative-side capacitor 84 is connected in series with the second contact point 64 on the resonant circuit 52 and the negative-side oscillating signal output end 96 so as to be positioned between the second contact point 64 and negative-side oscillating signal output end 96. The negative-side capacitor 84 can block the current that flows from the second contact point 64 to the negative-side oscillating signal output end 96.

The first amplification transistor 86 receives, at the base thereof, the oscillating signal 530 which has not been inverted and output from the first contact point 62 on the resonant circuit 52. The negative-side bias resistance 88 supplies a first bias voltage Vbias1 to the base of the first amplification transistor 86. The first amplification transistor 86 amplifies the received oscillating signal 530 which has not been inverted, and feeds the current obtained as a result of the amplification back to the second contact point 64 on the resonant circuit 52.

For example, the first amplification transistor 86 may be an npn transistor. If this is the case, the first amplification transistor 86 is connected at the base thereof to the wire between the positive-side oscillating signal output end 94 and the positive-side capacitor 82, is connected at the collector thereof to the second contact point 64, and is connected at the emitter thereof to the constant current circuit 80.

The first amplification transistor 86 functions as a switch that is connected to the second contact point 64 and constant current circuit 80 so as to be positioned therebetween. In other words, the first amplification transistor 86 is turned on when the voltage between the positive-side oscillating signal output end 94 and the positive-side capacitor 82 is higher than a reference voltage, and is turned off when the voltage between the positive-side oscillating signal output end 94 and the positive-side capacitor 82 is equal to or lower than the reference voltage.

The second amplification transistor 90 receives, at the base thereof, the oscillating signal 530 which has been inverted and output from the second contact point 64 on the resonant circuit 52. The positive-side bias resistance 92 supplies the first bias voltage Vbias1 to the base of the second amplification transistor 90. The second amplification transistor 90 amplifies the received oscillating signal 530 which has been inverted, and feeds the current obtained as a result of the amplification back to the first contact point 62 on the resonant circuit 52.

For example, the second amplification transistor 90 may be an npn transistor. If this is the case, the second amplification transistor 90 is connected at the base thereof to the wire between the negative-side oscillating signal output end 96 and the negative-side capacitor 84, is connected at the collector thereof to the first contact point 62, and is connected at the emitter thereof to the constant current circuit 80.

The second amplification transistor 90 functions as a switch that is connected to the first contact point 62 and the constant current circuit 80 so as to be positioned therebetween. In other words, the second amplification transistor 90 is turned on when the voltage between the negative-side oscillating signal output end 96 and the negative-side capacitor 84 is higher than a reference voltage, and turned off when the voltage between the negative-side oscillating signal output end 96 and the negative-side capacitor 84 is equal to or lower than the reference voltage.

The amplifier circuit 54 having the above-described configuration can invert and amplify the oscillating signal 530 which has not been inverted and is output from the first contact point 62 on the resonant circuit 52, and feed the resulting oscillating signal 530 back to the second contact point 64 on the resonant circuit 52. At the same time, the amplifier circuit 54 can invert and amplify the oscillating signal 530 which has been inverted and is output from the second contact point 64 on the resonant circuit 52, and feed the resulting oscillating signal 530 back to the first contact point 62 on the resonant circuit 52. As a consequence, the resonant circuit 52 and amplifier circuit 54 can amplify the oscillating signal 530 which has a predetermined frequency and is a differential signal based on positive feedback.

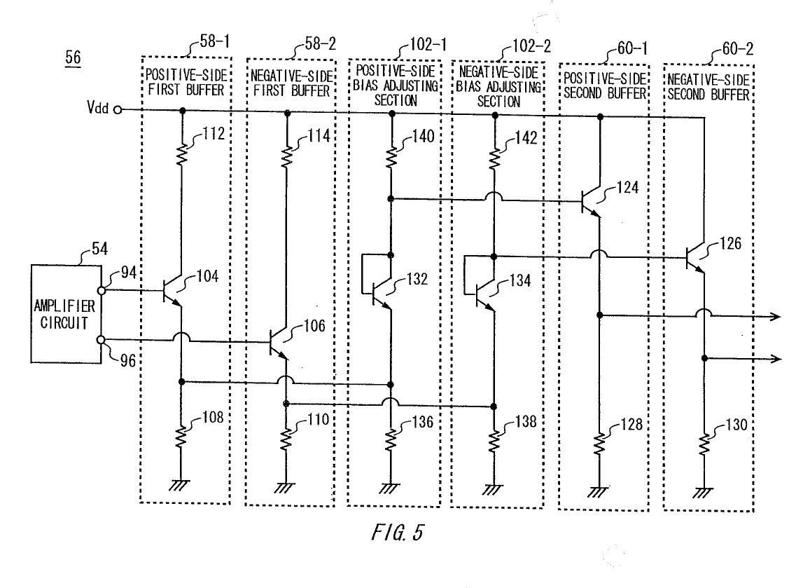

FIG. 5 illustrates an exemplary circuit configuration of the output circuit 56 which receives, from the amplifier circuit 54, the oscillating signal 530 which is a differential signal, together with the amplifier circuit 54. For example, the output circuit 56 may include therein a positive-side first buffer 58-1, a negative-side first buffer 58-2, a positive-side second buffer 60-1, a negative-side second buffer 60-2, a positive-side bias adjusting section 102-1, and a negative-side bias adjusting section 102-2.

The positive-side first buffer 58-1 includes a positive-side first buffer transistor 104. The base of the transistor 104 is connected to the positive-side oscillating signal output end 94 on the amplifier circuit 54. In other words, the base of the transistor 104 is connected to the base of the first amplification transistor 86. In addition, the transistor 104 is connected at the emitter thereof to the ground via a positive-side emitter resistance 108 in the first buffer 58, and is connected at the collector thereof to the power source voltage (Vdd) via a positive-side collector resistance 112 in the first buffer 58. The emitter of the transistor 104 is connected to the input end of the circuit of the following stage.

The transistor 104 that is connected in the above-described manner functions as an emitter follower circuit. Which is to say, when connected in the above-described manner, the transistor 104 can be connected at the collector thereof to ground, receive at the base thereof the oscillating signal 530 which has not been inverted and is supplied from the resonant circuit 52 to the amplifier circuit 54, and output from the emitter thereof the amplified oscillating signal 530 which has not been inverted to the circuit of the following stage. In the positive-side first buffer 58-1 having the above-described configuration, the transistor 104 has a relatively large capacitance component at the base end thereof. Therefore, the positive-side first buffer 58-1 can have a capacitance component at the input end thereof.

The negative-side first buffer 58-2 includes a negative-side first buffer transistor 106 which is connected and functions in a similar manner to the positive-side first buffer transistor 104. The base of the transistor 106 is connected to the negative-side oscillating signal output end 96 on the amplifier circuit 54. In other words, the base of the transistor 106 is connected to the base of the second amplification transistor 90. The transistor 106 is connected at the emitter thereof to ground via a negative-side emitter resistance 110 in the first buffer 58, and is connected at the collector thereof to the power source voltage (Vdd) via a negative-side collector resistance 114 in the first buffer. The emitter of the transistor 106 is connected to the input end of the circuit of the following stage.

The positive-side second buffer 60-1 includes a positive-side second buffer transistor 124 which is connected and functions in a similar manner to the positive-side first buffer transistor 104. The base of the transistor 124 is connected to the emitter of the transistor 104 in the first buffer 58. According to the present example, the base of the transistor 124 is connected to the emitter of the transistor 104 via a positive-side bias adjusting section 102-1. The transistor 124 is connected at the emitter thereof to ground via a positive-side emitter resistance 128 in the second buffer 60, and connected at the collector thereof to the power source voltage (Vdd). The emitter of the transistor 124 is connected to the input end of an external circuit of the following stage.

The negative-side second buffer 60-2 includes a negative-side second buffer transistor 126 which is connected and functions in a similar manner to the positive-side first buffer transistor 104. The base of the transistor 126 is connected to the emitter of the transistor 106 in the first buffer 58. According to the present example, the base of the transistor 126 is connected to the emitter of the transistor 106 via a negative-side bias adjusting section 102-2. The transistor 126 is connected at the emitter thereof to ground via a negative-side emitter resistance 130 in the second buffer 60, and connected at the collector thereof to the power source voltage (Vdd). The emitter of the transistor 126 is connected to the input end of an external circuit of the following stage.

Each of the positive-side bias adjusting section 102-1 and negative-side bias adjusting section 102-2 increases the bias level of the oscillating signal 530 output from the corresponding first buffer 58 in accordance with the amount of the voltage drop in the corresponding first buffer 58, and supplies the resulting oscillating signal 530 to the corresponding second buffer 60. For example, the positive-side bias adjusting section 102-1 may include a positive-side transistor 132 whose base and collector are connected to each other.

The emitter of the positive-side transistor 132 is connected to the emitter of the transistor 104 in the first buffer 58. The positive-side transistor 132 is connected at the emitter thereof to ground via a positive-side emitter resistance 136, and connected at the collector thereof to the power source voltage (Vdd) via a positive-side collector resistance 140. The collector of the positive-side transistor 132 is connected to the base of the transistor 124 in the second buffer 60. The positive-side transistor 132 connected in the above-described manner can increase the bias level of the oscillating signal 530 which has not been inverted and output from the emitter of the transistor 104 in accordance with the amount of the voltage drop in the transistor 104, and supply the resulting oscillating signal to the base of the transistor 124.

For example, the negative-side bias adjusting section 102-1 includes a negative-side transistor 134 which is connected and functions in a similar manner to the positive-side transistor 132. The emitter of the negative-side transistor 134 is connected to the emitter of the transistor 106 in the first buffer 58. Furthermore, the negative-side transistor 134 is connected at the emitter thereof to ground via a negative-side emitter resistance 138, and connected at the collector thereof to the power source voltage (Vdd) via a negative-side collector resistance 142. The collector of the negative-side transistor 134 is connected to the base of the transistor 126 in the second buffer 60.

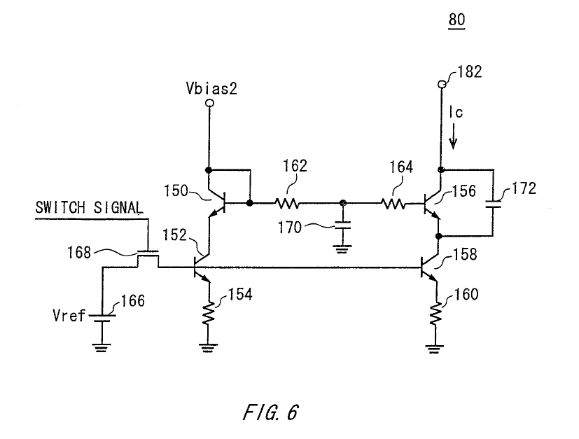

FIG. 6 illustrates an exemplary circuit configuration of the constant current circuit 80. The constant current circuit 80 includes therein a control transistor 150, a first bias transistor 152, a first reference resistance 154, a current source transistor 156, a second bias transistor 158, a second reference resistance 160, a first base resistance 162, a second base resistance 164, a reference voltage source 166, a main switch 168, a base connection capacitor 170, and a parallel capacitor 172.

The control transistor 150 is configured in such a manner that a short circuit is formed between the base and the collector and the collector is connected to the input end of a second bias Vbias2. The first bias transistor 152 is connected at the collector thereof to the emitter of the control transistor 150, and connected at the emitter thereof to ground via the first reference resistance 154. The first reference resistance 154 has a predetermined resistance value.

The current source transistor 156 may be a transistor which is the same type and has substantially the same characteristics as the control transistor 150. The current source transistor 156 is connected at the collector thereof to a load connection end 182 of the constant current circuit 80. The current source transistor 156 is connected to the first and second amplification transistors 86 and 90 in the amplifier circuit 54 via the load connection end 182.

The second bias transistor 158 is connected at the collector thereof to the emitter of the current source transistor 156, and connected at the emitter thereof to ground via the second reference resistance 160. The second reference resistance 160 has the same resistance value as the first reference resistance 154.

The first and second base resistances 162 and 164 are connected in series between the base of the control transistor 150 and the base of the current source transistor 156. Being connected in the above-described manner, the first bias transistor 152, current source transistor 156, first base resistance 162, and second base resistance 164 together function as a current mirror circuit. Consequently, the collector current flowing through the current source transistor 156 becomes the same as the collector current for the control transistor 150. The current source transistor 156 is provided between the ground potential and the first and second amplification transistors 86 and 90, so as to define the total of the collector currents of the first and second amplification transistors 86 and 90.

The reference voltage source 166 generates a reference voltage Vref. For example, the reference voltage source 166 may be a bandgap reference.

The main switch 168 is turned on/off in accordance with a switch signal that indicates whether the oscillator 20 performs the oscillation operation. The main switch 168 supplies the reference voltage Vref generated by the reference voltage source 166 to the base of the first bias transistor 152 while the switch signal indicates that the oscillator 20 performs the oscillation operation. The main switch 168 releases the connection between the reference voltage source 166 and the base of the first bias transistor 152 while the switch signal indicates that the oscillator 20 does not perform the oscillation operation.

As described above, while the switch signal indicates that the oscillator 20 performs the oscillation operation, the main switch 168 supplies the reference voltage Vref to the base of the first bias transistor 152, to cause a predetermined bias voltage to be generated between the collector and emitter of the first bias transistor 152. On the other hand, while the switch signal indicates that the oscillator 20 does not perform the oscillation operation, the main switch 168 supplies the ground potential to the base of the first bias transistor 152, to release the connection between the collector and emitter of the first bias transistor 152.

The base connection capacitor 170 is connected to the ground and the wire that is positioned between the first and second base resistances 162 and 164 so as to be positioned therebetween. The parallel capacitor 172 is disposed between the collector and the emitter of the current source transistor 156. The base connection capacitor 170 and parallel capacitor 172 can eliminate the high-frequency noise contained in the constant current flowing through the constant current circuit 80. Note that the parallel capacitor 172 can eliminate more high-frequency noise than when disposed between the collector of the current source transistor 156 and ground.

In the constant current circuit 80 having the above-described configuration, a predetermined bias voltage is generated between the collector and the emitter in each of the first and second bias transistors 152 and 158 while the switch signal indicates that the oscillator 20 performs the oscillation operation. Therefore, the collector current flowing through the control transistor 150 has a predetermined fixed value. Since the control transistor 150 and current source transistor 156 respectively function as current mirror circuits, the collector current flowing through the current source transistor 156 is in proportion to the collector current flowing through the control transistor 150. For example, the collector current flowing through the current source transistor 156 is the same as the collector current flowing through the control transistor 150. In this way, the constant current circuit 80 can supply a constant current to the first and second amplification transistors 86 and 90 when the oscillator 20 performs the oscillation operation.

In the constant current circuit 80 configured in the above-described manner, the connection between the collector and the emitter is released in each of the first and second bias transistors 152 and 158, while the switch signal indicates that the oscillator 20 does not perform the oscillation operation. Consequently, the collector current of the control transistor 150 becomes zero, and the collector current of the current source transistor 156 accordingly becomes zero. In this way, when the oscillator 20 does not perform the oscillation operation, the constant current circuit 80 can block the currents flowing through the first and second amplification transistors 86 and 90.

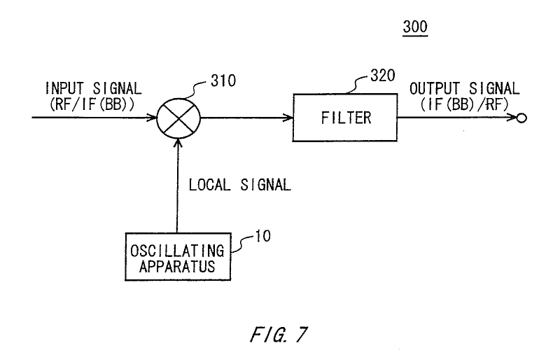

FIG. 7 illustrates the configuration of a frequency converting apparatus 300 relating to an embodiment of the present invention. The frequency converting apparatus 300 converts the frequency of an input signal in accordance with the frequency of a local signal.

For example, the frequency converting apparatus 300 may perform the frequency conversion in the following manner. The frequency converting apparatus 300 may multiply an RF signal with the local signal so as to convert the RF signal into an IF signal or baseband signal which has a lower frequency than the RF signal. As another example, the frequency converting apparatus 300 may multiply an IF signal or baseband signal with the local signal so as to convert the IF signal or baseband signal into an RF signal which has a higher frequency than the IF signal (or the baseband signal).

The frequency converting apparatus 300 includes therein the oscillating apparatus 10, a mixer 310 and a filter 320. The oscillating apparatus 10 generates the oscillating signal 530 which has a predetermined frequency, and outputs the oscillating signal 530 as the local signal. The oscillating apparatus 10 has the same configuration and functions as the oscillating apparatus 10 illustrated in FIG. 1, and is thus not described in detail in the following.

The mixer 310 multiplies together the local signal and input signal. For example, the mixer 310 may multiply together the RF signal and local signal. As an alternative example, the mixer 310 may multiply together the local signal and one of the IF signal and baseband signal.

The filter 320 passes therethrough a predetermined frequency component of the signal output from the filter 320. For example, the filter 320 may pass therethrough a low frequency component of the signal obtained by multiplying together the RF signal and local signal, and output the IF signal or baseband signal. As another example, the filter 320 may pass therethrough a high frequency component of the signal obtained by multiplying together the local signal and one of the IF signal and baseband signal, and output the RF signal. The frequency converting apparatus 300 having the above-described configuration can output a signal which has a frequency obtained by shifting the frequency of the input signal by an amount corresponding to the frequency of the local signal.

While an aspect of the present invention has been described through the embodiments, the technical scope of the invention is not limited to the above described embodiments. It is apparent to persons skilled in the art that various alternations and improvements can be added to the above-described embodiments. It is also apparent from the scope of the claims that the embodiments added with such alternations or improvements can be included in the technical scope of the invention.

What is claimed is:

1. An oscillating apparatus for outputting an oscillating signal, comprising:
a resonant circuit that generates the oscillating signal;
an amplifier circuit that amplifies the oscillating signal generated by the resonant circuit, and feeds the amplified oscillating signal back to the resonant circuit; and
an output circuit that receives the oscillating signal which is supplied to the amplifier circuit, and outputs the received oscillating signal to outside, wherein
the output circuit includes:
a first buffer that (i) receives at an input end thereof the oscillating signal which is supplied to the amplifier circuit and outputs the received oscillating signal, and (ii) uses a capacitance component of the input end to feed a first current signal back to the amplifier circuit, the first current signal having a phase displaced from a phase of a voltage component of the oscillating signal; and
a second buffer that (I) receives at an input end thereof the oscillating signal which is output from the first buffer and outputs the received oscillating signal, and (II) uses a capacitance component of the input end to feed a second current signal back to the first buffer, the second current signal having a phase displaced from a phase of a voltage component of the oscillating signal which is output from the first buffer.

2. The oscillating apparatus as set forth in claim 1, wherein
the first buffer is an emitter follower circuit that includes a first buffer transistor whose base receives the oscillating signal which is supplied to the amplifier circuit and whose collector is connected to ground, and
the second buffer is an emitter follower circuit that includes a second buffer transistor whose base receives the oscillating signal which is output from the first buffer transistor and whose collector is connected to ground.

3. The oscillating apparatus as set forth in claim 2, wherein
the output circuit further includes
a bias adjusting section that increases a bias level of the oscillating signal which is output from the first buffer transistor in accordance with an amount of a voltage drop in the first buffer transistor, and supplies the resulting oscillating signal to the base of the second buffer transistor.

4. The oscillating apparatus as set forth in claim 2, wherein
the amplifier circuit includes:
an amplification transistor that receives at a base thereof the oscillating signal which is generated by the resonant circuit and feeds a current in accordance with the received oscillating signal back to the resonant circuit; and
a bias resistance that supplies a bias voltage to the base of the amplification transistor, and
the base of the first buffer transistor is connected to the base of the amplification transistor.

5. The oscillating apparatus as set forth in claim 4, further comprising:
a current source transistor that is provided between the amplification transistor and a ground potential, the current source transistor defining a collector current of the amplification transistor; and
a parallel capacitor that is provided between an emitter and a collector of the current source transistor.

6. The oscillating apparatus as set forth in claim 5, wherein
the resonant circuit generates the oscillating signal which has a frequency determined in accordance with a control voltage supplied thereto and is a differential signal,
the amplification transistor of the amplifier circuit includes:
a first amplification transistor that receives at a base thereof the oscillating signal which is not inverted and amplifies the oscillating signal which is inverted based on the received oscillating signal; and
a second amplification transistor that receives at a base thereof the oscillating signal which is inverted and amplifies the oscillating signal which is not inverted based on the received oscillating signal, and
the current source transistor defines a total of a collector current of the first amplification transistor and a collector current of the second amplification transistor.

7. The oscillating apparatus as set forth in claim 6, wherein
the output circuit has a combination of the first and second buffers in correspondence with each of the first and second amplification transistors.

8. The oscillating apparatus as set forth in claim 1, further comprising
a phase comparator that compares a phase of the oscillating signal which is output from the output circuit with a phase of a reference clock, and controls a frequency of the oscillating signal based on a result of the comparison.

9. A frequency converting apparatus that converts a frequency of an input signal in accordance with a frequency of a local signal, comprising:
an oscillating apparatus that generates an oscillating signal and outputs the generated oscillating signal as the local signal;
a mixer that multiplies together the local signal and the input signal; and
a filter that passes therethrough a predetermined frequency component of a signal output from the mixer, wherein
the oscillating apparatus includes:
a resonant circuit that generates the oscillating signal;
an amplifier circuit that amplifies the oscillating signal which is generated by the resonant circuit and feeds the amplified oscillating signal back to the resonant circuit; and
an output circuit that receives the oscillating signal which is supplied to the amplifier circuit and outputs the received oscillating signal to outside, and
the output circuit includes:
a first buffer that (i) receives at an input end thereof the oscillating signal which is supplied to the amplifier circuit and outputs the received oscillating signal, and (ii) uses a capacitance component of the input end to feed a first current signal back to the amplifier circuit, the first current signal having a phase displaced from a phase of a voltage component of the oscillating signal; and
a second buffer that (I) receives at an input end thereof the oscillating signal which is output from the first buffer and outputs the received oscillating signal, and (II) uses a capacitance component of the input end to feed a second current signal back to the first buffer, the second current signal having a phase displaced from a phase of a voltage component of the oscillating signal which is output from the first buffer.
